(19) United States
(12) Patent Application Publication
(10) Pub. No.: US 2011/0186884 A1
(43) Pub. Date: Aug. 4, 2011

(54) LED Reflective Structure and Method of Fabricating the Same

(75) Inventors: Cheng-Yi Liu, Jhongli City (TW); Po-Han Chang, Jhongli City (TW)

(73) Assignee: NATIONAL CENTRAL UNIVERSITY, Taoyuan County (TW)

(21) Appl. No.: 12/699,160

(22) Filed: Feb. 3, 2010

(51) Int. Cl. H01L 33/00; H01L 21/30

(52) U.S. Cl. 257/98; 438/29; 257/E33.068; 257/E21.211

(57) ABSTRACT

A reflective structure is fabricated for a light emitting diode (LED). An ohmic contact layer of the LED is made into a netlike structure. Thus, a current is evenly distributed and a low contact resistance is remained. Furthermore, the reflective layer directly reflects light through holes of the netlike structure on emitting light. Thus, a reflectivity of the LED is enhanced.

### FIELD OF THE INVENTION

The present invention relates to a light emitting diode (LED); more particularly, relates to covering a reflective layer over an ohmic contact layer having a netlike structure and pasting a metal material for packaging thin film LEDs or flip chip LEDs with a reflectivity enhanced and a low contact resistance remained.

### DESCRIPTION OF THE RELATED ARTS

Solid-state lighting technologies are rapidly developed recently; more particularly, GaN-based LED has a high brightness and thus becomes a future.

As shown in FIG. 7 to FIG. 9, a thin film structure 3a, a flip chip structure 3b or a thin-film flip-chip structure 3c comprises a substrate 31, a LED 32, an ohmic contact layer 33 and a reflective layer 34. The flip chip structure 3b further comprises a sapphire substrate 35. Comparing to a wire-bonding structure, the prior two structures 3a,3b are proved to have better light extraction efficiencies and thermal managements. In the flip chip structure and the thin film structure, a p-type semiconductor having a high reflectivity, like Al and Au, is required to enhance a light emitting efficiency of the chip. Moreover, a good ohmic contact metal is also required, like a combination of Ni/Au, Pd/Ni/Au or Pd/Au. After a thermal treatment of the combination at 500° C. to 600° C., a contact resistance between 10⁻⁴ and 10⁻⁶ Ω-cm² can be achieved. However, as shown in FIG. 10, after combining the ohmic contact layer 33 and the reflective layer 34, a part of light is absorbs by the ohmic contact layer 33 and thus a reflectivity of the whole structure and its light extraction efficiency are reduced.

In the other hand, traditional technologies in transparent conducting layer are focused on conductive ceramics, like ITO, AZO or other contact metal alloy. However, these traditional transparent conducting layers have problems in fresnel loss and insufficient transmittance. Hence, the prior arts do not fulfill all users' requests on actual use.

### SUMMARY OF THE INVENTION

The main purpose of the present invention is to enhance a reflectivity of a reflective layer and to remain a low contact resistance.

The second purpose of the present invention is to fabricate a netlike structure of an ohmic contact layer and to further cover a reflective layer for evenly distributing a current with the low contact resistance remained.

The third purpose of the present invention is to directly reflect light through holes in the netlike structure of the ohmic contact layer for enhancing the reflectivity of the reflective layer.

To achieve the above purpose, the present invention is a LED reflective structure and a method of fabricating the same, where the LED reflective structure comprises a LED wafer, an ohmic contact layer and a reflective layer; the LED wafer comprises a substrate and a light-emitting epitaxial structure; the epitaxial structure is obtained on the substrate through epitaxy; the ohmic contact layer has a netlike structure; the ohmic contact layer is obtained on the LED wafer; the reflective layer is covered over the netlike structure of the ohmic contact layer; a method of fabricating the LED reflective structure comprises steps of: (a) growing a light-emitting epitaxial structure on a substrate through epitaxy to obtain a LED wafer; (b) obtaining an ohmic contact layer on a surface of the LED wafer through evaporation deposition; (c) obtaining a netlike structure of the ohmic contact layer; and (d) covering a reflective layer over the netlike structure of the ohmic contact layer. Accordingly, a novel LED reflective structure and a method of fabricating the same are obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the view showing the structure of the preferred embodiment according to the present invention;

FIG. 2 is the view showing the package of the preferred embodiment;

FIG. 3 is the view showing the fabrication flow of the preferred embodiment;

FIG. 4 is the view showing the first state of the fabrication;

FIG. 5 is the view showing the second state of the fabrication;

FIG. 6 is the view showing the third state of the fabrication;

FIG. 7 is the view of the first prior art;

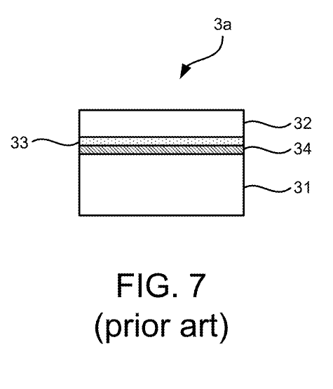

FIG. 8 is the view of the second prior art;

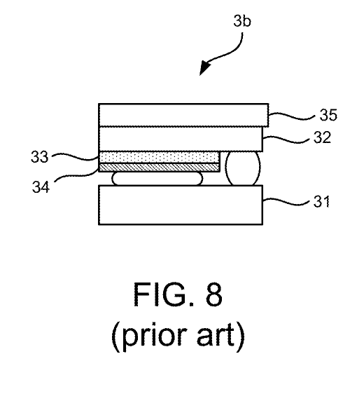

FIG. 9 is the view of the third prior art; and

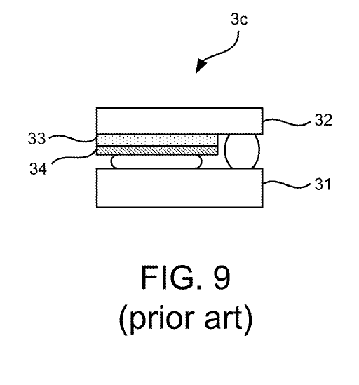

FIG. 10 is the view of the reflection loss.

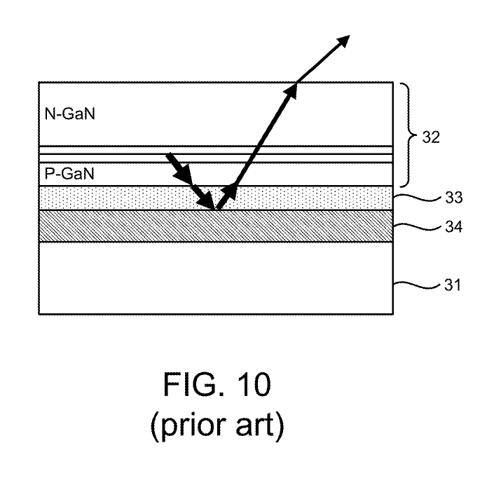

### DESCRIPTION OF THE PREFERRED EMBODIMENT

The following description of the preferred embodiment is provided to understand the features and the structures of the present invention.

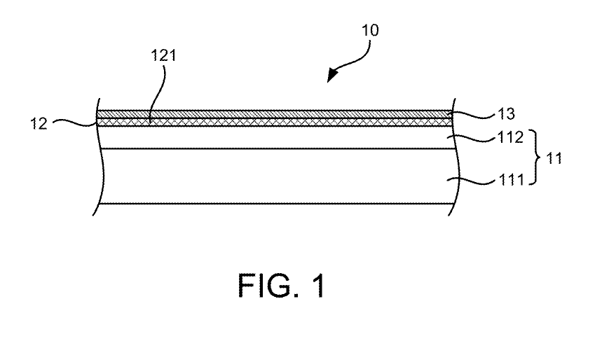

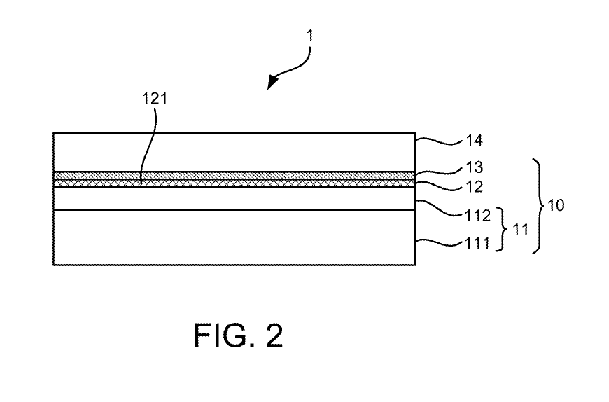

Please refer to FIG. 1 and FIG. 2, which are views showing a structure and a package of a preferred embodiment according to the present invention. As shown in the figures, the present invention is a light emitting diode (LED) reflective structure and a method of fabricating the same. The LED reflective structure 10 comprises a LED wafer 11, an ohmic contact layer 12 and a reflective layer 13.

The LED wafer 11 comprises a substrate 111; and a light-emitting epitaxial structure 112 grown on the substrate 111 through epitaxy, where the LED wafer is made of silicon, glass, GaAs, GaN, AlGaAs, GaP, SiC, InP, BN, ZnO, AlO or AlN.

The ohmic contact layer 12 has a netlike structure; and is formed on the LED wafer 11, where the ohmic contact layer 12 is made of a metal, a metal oxide, a ceramic material, a semiconductor or a composite material; a surface of the netlike structure is not intact but with holes 121; the holes 121 have geometrical figures; and sizes and an occupation rate of the holes 121 are not limited.

The reflective layer 13 is covered over the netlike structure of the ohmic contact layer 11, where the reflective layer 13 is a multi-layer reflector made of materials having various refractivity; and the material can be metal. Thus, a novel LED reflective structure 10 is obtained.

The LED reflective structure 10 can be further pasted with a metal material for packaging thin film LEDs or flip chip LEDs to obtain LED chips 1.

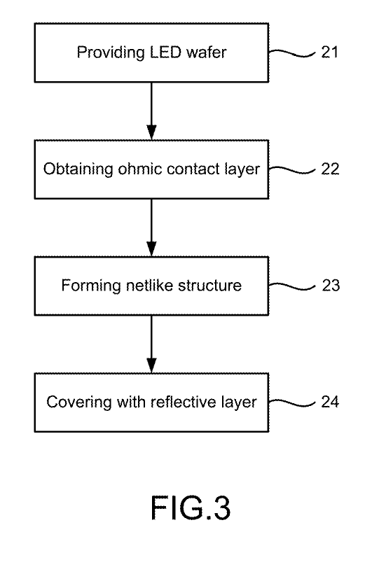

Please refer to FIG. 3 to FIG. 6, which are a view showing a fabrication flow of the preferred embodiment; and views showing a first to a third states of the fabrication. As shown in the figures, a method of fabricating a LED reflective structure according to the preferred embodiment comprises the following steps:

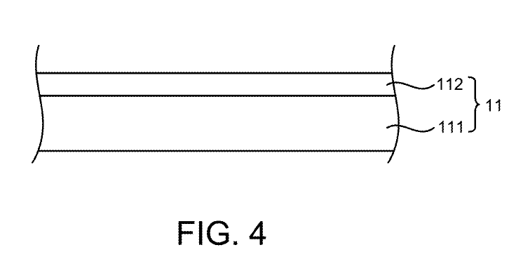

(a) Providing LED wafer 21: As shown in FIG. 4, a light-emitting epitaxial structure 112 is grown on a substrate 111 through epitaxy to provide a LED wafer 11 for emitting light through photoelectric effect.

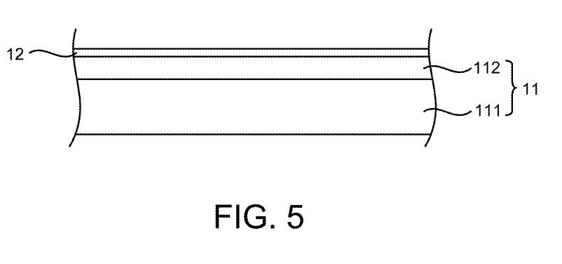

(b) Obtaining ohmic contact layer 22: As shown in FIG. 5, an ohmic contact layer 12 of platinum film is obtained on a surface of the LED wafer 11 through evaporation deposition.

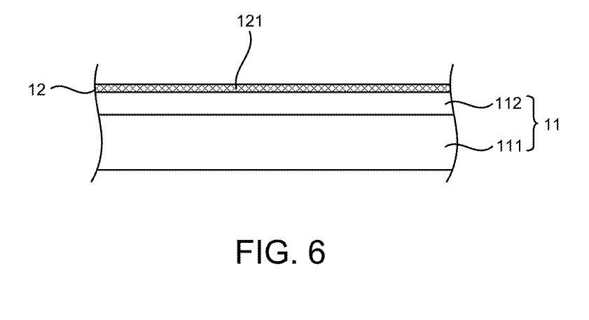

(c) Forming netlike structure 23: As shown in FIG. 6, a netlike structure of the ohmic contact layer 12 is formed through lithography, dry etching, wet etching, thermal treatment, laser treatment, ion beam irradiation or sintering.

(d) Covering with reflective layer 24: As shown in FIG. 1, at last, a reflective layer 13 is covered over the netlike structure of the ohmic contact layer 12 to obtain a LED reflective structure 10.

After covering the reflective layer over the netlike structure of the ohmic contact layer 12, a metal material 14 can be further pasted for packaging thin film LEDs or flip chip LEDs.

With the netlike structure, a current is evenly distributed and a low contact resistance is remained. Furthermore, the reflective layer 13 directly reflects light through the holes 121 in the netlike structure to enhance a reflectivity of the LED reflective structure 10.

To sum up, the present invention is a LED reflective structure and a method of fabricating the same, where a current is evenly distributed; a low contact resistance is remained; and, by obtaining a netlike structure of an ohmic contact layer, a reflective layer directly reflects light through holes in the netlike structure to enhance a reflectivity of a LED reflective structure.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A light emitting diode (LED) reflective structure, comprising:
a LED wafer, said LED wafer comprising a substrate and a light-emitting epitaxial structure, said epitaxial structure being obtained on said substrate through epitaxy;
an ohmic contact layer, said ohmic contact layer having a netlike structure, said ohmic contact layer being obtained on said LED wafer; and
a reflective layer, said reflective layer being covered over said netlike structure of said ohmic contact layer,
wherein a current is evenly distributed on said netlike structure of said ohmic contact layer to obtain a low contact resistance; and
wherein said reflective layer directly reflects light through holes in said netlike structure to enhance a reflectivity of said LED reflective structure.

2. The LED reflective structure according to claim 1,
wherein said reflective layer is further pasted with a metal for packaging LEDs selected from a group consisting of thin film LEDs and flip chip LEDs.

3. The LED reflective structure according to claim 1,
wherein said LED wafer is made of a material selected from a group consisting of silicon, glass, GaAs, GaN, AlGaAs, GaP, SiC, InP, BN, ZnO, AlO and AlN.

4. The LED reflective structure according to claim 1,
wherein said ohmic contact layer is made of a material selected from a group consisting of a metal, a metal oxide, a ceramic material, a semiconductor and a composite material.

5. The LED reflective structure according to claim 1,
wherein a surface of said netlike structure is not intact and said netlike structure has holes.

6. The LED reflective structure according to claim 1,
wherein said reflective layer is a multi-layer reflector made of materials having various refractivity.

7. The LED reflective structure according to claim 6,
wherein said material is metal.

8. The LED reflective structure according to claim 1,
wherein a method of fabricating said LED reflective structure comprises steps of:
(a) growing a light-emitting epitaxial structure on a substrate through epitaxy to obtain a LED wafer;
(b) obtaining an ohmic contact layer on a surface of said LED wafer through evaporation deposition;
(c) obtaining a netlike structure of said ohmic contact layer; and
(d) covering a reflective layer over said netlike structure of said ohmic contact layer.

9. The LED reflective structure according to claim 8,
wherein said method of fabricating said LED reflective structure further comprises a step of pasting said reflective layer with a metal for packaging LEDs selected from a group consisting of thin film LEDs and flip chip LEDs.

10. The LED reflective structure according to claim 8,
wherein said LED wafer is made of a material selected from a group consisting of silicon, glass, GaAs, GaN, AlGaAs, GaP, SiC, InP, BN, ZnO, AlO and AlN.

11. The LED reflective structure according to claim 8,
wherein said ohmic contact layer is made of a material selected from a group consisting of a metal, a metal oxide, a ceramic material, a semiconductor and a composite material.

12. The LED reflective structure according to claim 8,
Wherein, in step (c), said netlike structure of said ohmic contact layer is obtained through a method selected from a group consisting of lithography, dry etching, wet etching, thermal treatment, laser treatment, ion beam irradiation and sintering.

13. The LED reflective structure according to claim 8,
wherein said reflective layer is a multi-layer reflector made of a plurality of materials having various refractivity.
